(19) United States
(12) Patent Application Publication
(10) Pub. No.: US 2011/0315215 A1
(43) Pub. Date: Dec. 29, 2011

(54) COLOR BUILDING-INTEGRATED PHOTOVOLTAIC (BIPV) MODULE

(75) Inventors: Liang-Jyi CHEN, Taipei City (TW); Hung-Chun TSAI, Hsinchu City (TW); Yu-Ting LIN, Hsinchu City (TW)

(73) Assignee: DU PONT APOLLO LTD., Hong Kong (HK)

(21) Appl. No.: 13/169,788

(22) Filed: Jun. 27, 2011

Related U.S. Application Data
(60) Provisional application No. 61/359,139, filed on Jun. 28, 2010.

(51) Int. Cl. H01L 31/0216; B32B 38/00; H01L 31/18; H01L 31/0264; H01L 31/036

(52) U.S. Cl. 136/256; 156/244.11

(57) ABSTRACT

The present invention provides a color backsheet for a building-integrated photovoltaic (BIPV) module comprising a polyethylene terephthalate (PET) film, a barrier layer and a fluorine-containing polymer film, at least one of the films being doped with dyes or pigments. The present invention also provides a color BIPV module comprising the color backsheet according to the present invention.

### FIELD OF THE INVENTION

The present invention relates to a color building-integrated photovoltaic (BIPV) module. More particularly, the present invention relates to the manufacture of a color backsheet which is useful in a color BIPV module.

### BACKGROUND OF THE INVENTION

A BIPV is a photovoltaic material that is particularly used to replace traditional building materials in parts of the building envelope such as roofs, skylights, or facades. BIPVs are increasingly being incorporated into the construction of buildings as an ancillary source, even a principal source, of electrical power. BIPVs can be colorful and visually arresting, and since BIPVs are an integral part of the design, they are generally blend in better than other solar devices. In the past decade, BIPV is proving to be an effective building energy technology in residential, commercial, industrial, and institutional buildings and structures.

BIPVs also give shade from the sun as well as protection from wind and rain. In addition, when the weather is cold, non-ventilated BIPV modules can provide thermal insulation. This means that less energy is wasted by heat loss from the interior and reducing heating costs. When the weather is hot, BIPV absorbs the energy of the rays from the sun so as to keep the building at an ambient temperature.

Various color BIPV structures have been disclosed in literatures.

JP 02-094575 discloses a photovoltaic device with a colored protective film. In the photovoltaic device, the color is provided by adding pigments such as iron oxide red, aluminum, and Asarin lake pigment of tin to colorless transparent fluorine resin and screen printed on the ITO film.

WO 2007/134742 discloses a color-sensitized solar cell comprising a light-absorbing and mono-molecular dye layer.

JP 2004-200322 discloses a color solar cell module with a rear surface protective sheet. An evaporated film of inorganic oxide is formed on one surface of a base film. A heat-resistant polyolefin resin film containing a coloring additive agent, an ultraviolet absorber, and a light stabilizer is laminated on the one surface of the base film where the inorganic oxide evaporated film has been deposited. A heat-resistant polyolefin resin film containing a coloring additive agent different in shade from the above coloring additive agent, an ultraviolet absorber, and a light stabilizer is laminated on the other surface of the other surface of the base film for the formation of the rear surface protective sheet.

JP 2001-53298 discloses a solar cell with a color toning adhesive film configured between a surface transparent protective film and a silicon voltaic element.

US 2003/0178058 provides a colored solar cell unit. It is disclosed that some parts of the surface of the solar cell unit do not generate energy. By providing a coloring material above at least part of the non-energy-generating part and leaving at least part of the energy-generating part of the solar cell unit free of a coloring material, the solar cell unit can be colored while the output of the solar cell unit is not affected.

JP 61-196584 discloses an a-Si photovoltaic element comprising a blue-colored protective film, a white-colored protective film and a red-colored protective film to prevent deterioration due to intense light and to increase the arbitrariness in designing an a-Si photovoltaic element.

However, a dyed electrode layer inevitably reduces the transparency so the light energy available to be absorbed by the photoconversion layer is decreased. In addition, the dyes or pigments in an encapsulant layer, for example, an EVA layer, could significantly reduce the adhesion strength of a BIPV module to the envelope of a building, especially when the BIPV module is to be mounted on glass materials. Given the above, there is still a need for a new BIPV module without the above disadvantages.

### SUMMARY OF THE INVENTION

The present invention provides a novel color backsheet which is useful in a BIPV module and a process for producing the color backsheet. The color backsheet according to the present invention does not have the above mentioned disadvantages and retain the weather resistance of the weather film.

The color backsheet according to the present invention comprises:
a polyethylene terephthalate (PET) film;
a barrier layer; and
a fluorine-containing polymer film,
wherein the PET film and/or the fluorine-containing polymer film comprises supporting carrier particles and dyes or pigments.

The method for producing the color backsheet according to the present invention comprises the steps of:
a) mixing supporting carrier particles and dyes or pigments by a sol-gel process;
b) compounding the mixture obtained in a) with a fluorine-containing polymer material or PET;
c) extruding the product obtained in b) to form a color fluorine-containing polymer film or a color PET film; and
d) laminating the color fluorine-containing polymer film or the color PET film obtained in c) with a barrier layer and a color/transparent PET film or a color/transparent fluorine-containing polymer film to form the color backsheet.

The present invention also provides a color BIPV module comprising:
a transparent substrate;
a first electrode layer;
a light absorbing layer;
a second electrode layer;
an encapsulant layer; and
the color backsheet according to the present invention.

The method for producing the color BIPV module according to the present invention includes the steps of:
a) providing a transparent substrate;
b) depositing a first electrode layer;
c) depositing a light absorbing layer;
d) depositing a second electrode layer;
e) laminating the structure obtained in d) with an encapsulant layer; and
f) laminating the structure obtained in e) with the color backsheet according to the present invention.

### BRIEF DESCRIPTION OF THE DRAWING

FIG. 1 shows a schematic structure of a color BIPV according to the present invention. The color BIPV according to the present invention comprises: a transparent substrate (101), a first electrode layer (102), a light absorbing layer (103), a second electrode layer (104), an encapsulant layer (105) and a color backsheet (106) which is comprised of a PET layer (1061, either color or transparent), a barrier layer (1062) and a fluorine-containing polymer layer (1063, either color or transparent).

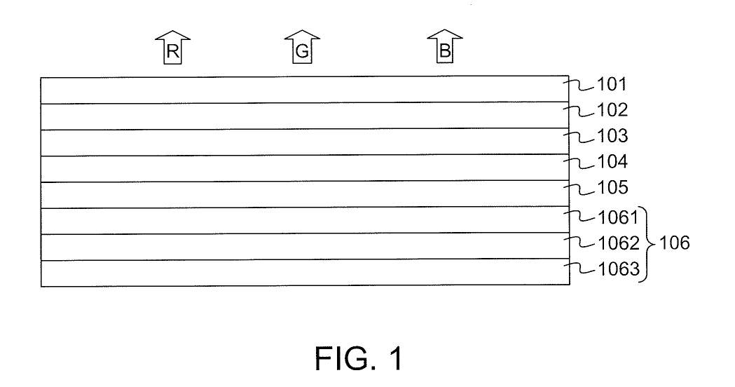

### DETAILED DESCRIPTION OF THE INVENTION

The present invention is illustrated below in detail by the embodiments with reference to the drawing, which is not intended to limit the scope of the present invention. It will be apparent that any modifications or alterations that are obvious for persons skilled in the art fall within the scope of the disclosure of the specification.

One aspect of the present invention is to provide a novel color backsheet for a BIPV module.

The color backsheet according to the present invention is comprised of a PET film, a barrier layer and a fluorine-containing polymer film.

The PET film is to provide electrical insulation. The PET film should have a volume resistivity in a range of 10¹² ohm-cm to 10¹⁵ ohm-cm.

The barrier layer, such as an aluminum foil, is to provide moisture resistance. The Al foil has a moisture permeability of less than 10⁻⁴g/m²·day. The thickness of the barrier layer is not particularly limited and is preferred 10 μm to 100 μm, more preferably 20 μm to 50 μm.

The fluorine-containing polymer film is preferably made of polyvinylidene difluoride (PVDF), polyvinyl fluoride (PVF) or ethylene tetrafluoroethylene (ETEF), or a combination thereof. The fluorine-containing polymer film serves as a weather resistant film and is to provide UV resistance and weather resistance. The fluorine-containing polymer film should have a moisture permeability of 3 to 50 g/m²·day, preferably 3 to30g/m²·day, most preferably 10 to 30 g/m²·day.

Dyes and pigments of desired color are incorporated into the PET and/or the flourine-containing film. Suitable dyes or pigments include, but not limit to, Rohanimide dye, azo dye, phthalocyanine dye, Pig Gr 10 (Nickel, 3-[4-(chlorophenyl)azo]-4-hydroxy-2-(1H)-quinolineone complex), Pig Blue 15 ((phthalocyaninato(2-))copper)), Sol Yell 16 (2,4-dihydro-5-methyl-2-phenyl-4-(phenylazo)-3h-pyrazol-3-on), Sol Or 1 (p-phenylazoresorcinol), Sol Red 1 (1-(o-anisylazo)-2-naphthol), Pig Yell 37 (cadmiummonsulfide), Pig Blue 33 (Manganese Blue), Pig Blue 29 (ultramarine blue), Pig Gr 17 (chromium trioxide green), Pig Blk 11 (iron (II, III) oxide, black), Pig Metal 1 (aluminum) and Pig Metal 2 (copper). To well disperse the dyes or pigments, the dyes or pigments are first mixed with supporting carrier particles by a sol-gel process and then compound and extrude with a PET or a fluorine-containing polymer precursor solution to form a color PET or fluorine-containing polymer film. A sol-gel process is a skill known in the art. Preferred supporting carrier particles of the present invention are metal oxides (such as TiO₂) and SiO₂. particles having a particle size of 9 μm to 500 μm. The color PET or fluorine-containing film is then laminated with a barrier layer and a color/transparent fluorine-containing polymer or PET film to form the color backsheet of the present invention.

The color backsheet according to the present invention can be prepared by the process comprising the steps of:
a) mixing supporting carrier particles and dyes or pigments by a sol-gel process;
b) compounding the mixture obtained in a) with PET or a fluorine-containing polymer;
c) extruding the product obtained in b) to form a color PET or a fluorine-containing film; and
d) laminating the color PET or fluorine-containing film obtained in c) with a barrier layer and a color/transparent fluorine-containing polymer or a color/transparent PET film to form the color backsheet.

The above mixing, compounding, extruding and laminating techniques are known in the art of materials science and have been disclosed in various literatures.

For example, the color backsheet according to the present invention can be prepared by the following exemplified process:
a) heterocoagulating TiO₂ or SiO₂/TiO₂ nanoparticles with poly(acrylic acid-co-methyl methacrylate) (poly(AA-co-MMA)) nanoparticles. TiO₂ or SiO₂/TiO₂ nanoparticles are prepared by hydrolysis and condensation at 100 to 150° C. in aqueous DMF(N,N-dimethylmethanamide) or toluene media, followed by mixing with poly(AA-co-MMA) and pigments or dyes to form composite particles;
b) compounding the composite particles obtained in a) with PET (or fluorine-containing polymer) pellets, an anti-UV agent(e.g., Cyasorb® UV-531, Cytec Industries Inc.), an anti-oxidant (e.g., ETHANOX® 330, Albemarle Corporation), and a radical trapping agent (e.g., Tinuvin® 292, Ciba Inc.) at 130 to 150° C.;
c) extruding the product obtained in b) to form a color PET (or fluorine-containing polymer)film; and
d) laminating the product obtained in c), a barrier layer of 20 to 50 μm, a fluorine-containing polymer (or PET) film of 150 to 250 μm, and Adhesives 506® (DuPont)at 70 to 100° C.

Another aspect of the present invention is to provide a color BIPV module. The color BIPV module comprises:
a transparent substrate;
a first electrode layer;
a light absorbing layer;
a second electrode layer;
an encapsulant layer; and
the color backsheet according to the present invention.

The substrate and the first electrode layer are preferred to be transparent to allow sunlight to pass through.

The substrate can be any transparent material and glass is preferred.

The first electrode layer can be made of any suitable materials. In one embodiment of the present invention, the material for the first electrode layer is a transparent conducting oxide (TCO). Suitable TCO materials include metal oxides of Ag, Al, Cu, Cr, Zn, Mo, Wo, Ca, Ti, In, Sn, Ba, Ti or Ni. The TCO layer may be optionally doped with metals such as Al, Ga and Sb. Preferred materials for the first electrode layer according to the present invention are indium tin oxide(ITO), tin oxide doped with fluorine(FTO), SnO₂ and SnO₂ doped with Sb (ATO).

The light absorbing layer according to the present invention is made of a material which is capable of transforming light energy into electric energy. Preferred materials for the light absorbing layer according to the present invention are amorphous silicon (a-Si), copper indium diselenide (CIS), copper indium gallium diselenide (CIGS), multicrystalline silicon (mc-Si) and polycrystalline silicon (poly-Si). The light absorbing layer can be of any types such as single-, tandem- or triple-junction elements and they can be made by suitable means described in publications, for example, U.S. Pat. No. 5,334,259.

The second electrode layer can be transparent, semi-transparent or even opaque. In one embodiment of the present invention, the second electrode layer is made of an abovementioned TCO or a metal film such as Ag, Cr and Al, or a combination of a TCO and a metal film. The metal film preferably has a thickness of 30 to 100 A, more preferably 50 to 100 A.

The encapsulant layer according to the present invention is made of ethylene-vinyl acetate (EVA) or polyvinyl butyral (PVB), preferably EVA.

The process for making a BIPV module is a skill known in the art.

For example, the color BIPV module can be prepared by the steps of:
a) providing a glass substrate;
b) depositing a layer of SnO₂ (about 3600 A) on the glass substrate as a first electrode layer by sputtering or atmospheric pressure chemical vapor deposition (APCVD);
c) depositing a layer of PIN a-Si layer as a light absorbing layer on the first electrode layer by PECVD;
d) depositing an Ag layer having a thickness of 30 to 100 A and a layer of SnO₂ on the light absorbing layer as the second electrode; and
e) laminating the structure obtained in d) with a layer of EVA and the color backsheet according to the present invention.

What is claimed is:

1. A color backsheet for building-integrated photovoltaic (BIPV) module comprising:
a polyethylene terephthalate (PET) film;
a barrier layer; and
a fluorine-containing polymer film,
wherein the PET film or the fluorine-containing polymer film or both comprise supporting carrier particles and dyes or pigments.

2. The color backsheet of claim 1, wherein the supporting carrier particles are TiO₂ particles.

3. The color backsheet of claim 1, wherein the fluorine-containing polymer material is selected from the group consisting of polyvinylidene difluoride (PVDF), polyvinyl fluoride (PVF), ethylene tetrafluoroethylene (ETEF) and a combination thereof.

4. The color backsheet of claim 1, wherein the barrier layer is an aluminum foil.

5. The color backsheet of claim 1, wherein the barrier layer is with a thickness of 10 μm to 100 μm.

6. The color backsheet of claim 5, wherein the barrier layer is with a thickness of 20 μm to 50 μm.

7. A method for producing a color backsheet for building-integrated photovoltaic module comprising the steps of:
a) mixing carrier particles and dyes or pigments by a sol-gel process;
b) compounding the mixture obtained in a) with PET;
c) extruding the product obtained in b) to form a color PET film; and
d) laminating the color PET film obtained in c) with a barrier layer and a color or transparent fluorine-containing polymer film.

8. A method for producing a color backsheet for building-integrated photovoltaic module comprising the steps of:
a) mixing carrier particles and dyes or pigments by a sol-gel process;
b) compounding the mixture obtained in a) with a fluorine-containing polymer;
c) extruding the product obtained in b) to form a color fluorine-containing polymer film; and
d) laminating the color fluorine-containing polymer film obtained in c) with a barrier layer and a color or transparent PET film.

9. A color BIPV module comprising:
a transparent substrate;
a first electrode layer;
a light absorbing layer;
a second electrode layer;
an encapsulant layer; and
the color backsheet as defined in claim 1.

10. The color BIPV module of claim 9, wherein the transparent substrate is a glass substrate.

11. The color BIPV module of claim 9, wherein the first electrode is a film made of a material selected from the group consisting of indium tin oxide (ITO), tin oxide doped with fluorine (FTO), SnO₂ and SnO₂ doped with Sb (ATO).

12. The color BIPV module of claim 9, wherein the light absorbing layer is a film of amorphous silicon (a-Si), copper indium diselenide (CIS), copper indium gallium diselenide (CIGS), multicrystalline silicon (mc-Si) or polycrystalline silicon (poly-Si).

13. The color BIPV module of claim 9, wherein the second electrode is a film made of ITO, FTO, SnO₂ or ATO or a thin metal film selected from Ag, Cr or Al and having a thickness of 30 to 100 A.

14. The color BIPV module of claim 9, wherein the encapsulant layer is made of ethylene vinyl acetate (EVA).
